(19) United States
(12) Patent Application Publication
(10) Pub. No.: US 2009/0283141 A1
(43) Pub. Date: Nov. 19, 2009

(54) Solar Cells and Methods for Manufacturing Same

(75) Inventors: Andreas Bentzen, Oslo (NO); Erik Sauar, Oslo (NO)

Correspondence Address: BIRCH STEWART KOLASCH & BIRCH, PO BOX 747, FALLS CHURCH, VA, 22040-0747, US

(73) Assignee: Renewable Energy Corporation ASA, Hevik (NO)

(21) Appl. No.: 12/226,133

(22) PCT Filed: Apr. 12, 2007
(86) PCT No.: PCT/NO2007/000130

§ 371 Date: Mar. 11, 2009

(30) Foreign Application Priority Data
Apr. 12, 2006 (NO) 2006 1668

(51) Int. Cl. H01L 31/0216; H01L 31/02; H01L 31/028; H01L 31/0368

(52) U.S. Cl. 136/256; 438/83; 136/261; 136/258; 438/98; 257/E31.11

(57) ABSTRACT

This invention relates to a method for contacting solar wafers containing one or more layers of temperature sensitive passivation layers by first creating local openings in the passivation layer(s) and then fill the openings with an electric conducting material. In this way, it becomes possible to avoid the relatively high temperatures needed in the conventional method for contacting solar wafers containing one or more passivation layer(s), and thus maintain the excellent passivation properties of newly developed temperature sensitive passivation layer(s) during and after the contacting.

### FIELD OF THE INVENTION

The present inventions relates to manufacturing of solar cells. More specifically, the invention relates to concepts for achieving an increased energy conversion efficiency of solar cells, and methods for manufacturing such solar cells of increased efficiency.

### BACKGROUND

It is widely known that a bare silicon sample contains many surface states; at which injected or photogenerated minority carriers can recombine. Thus, for devices where transports of minority carriers are crucial for efficient operation, such as in silicon based solar cells, reduction of the surface recombination velocity by a surface passivation technique is a vital issue.

A recent development in passivation of silicon based solar cells shows very promising results; the use of a combined amorphous silicon film and a silicon nitride film on the surface(s) of the silicon wafer. The use of this combined passivation of silicon based solar cells is disclosed in South-Korean patent application No. 2002-0018204. More particularly, the patent application discloses depositing a first layer of amorphous silicon with thickness in the range of 1-20 nm, followed by depositing a layer of silicon nitride with refractive index in the range of 1.9-2.3. Both layers may be deposited by PECVD (plasma enhanced chemical vapour deposition), and it should be applied on at least the light-receiving side of the solar cell.

The present inventors have improved the passivation technique of South-Korean patent application No. 2002-0018204 by introducing an annealing step after deposition of the second silicon nitride layer. This technique is disclosed in U.S. provisional application US 60/671,081 and in an article by Andreas Bentzen et al. [1]. Both documents are incorporated into this application by reference. Their studies of the effect of annealing on the effective recombination lifetimes shows that annealing at temperatures in the range from about 300 to about 550° C. gives significantly enhanced recombination lifetimes, and that there is maximum effect at around 500° C. At temperatures below or above this window, the recombination lifetimes become significantly lower. The enhancement of the recombination lifetimes is believed to be due to diffusion of hydrogen into silicon substrate close to the interface region silicon substrate/amorphous silicon film. The decrease of recombination lifetimes when the passivation layer is annealed or heated to temperatures above 550° C. is shown to be due to defects created in the interface region resulting from out-effusion of the hydrogen in the silicon substrate.

The temperature sensitivity of many passivation techniques/layers presented above represents a troublesome restriction for the subsequent processing of the solar wafers to solar panels. For instance, the presently conventional way of contacting the wafers involves screen printing a paste comprising a metallic phase and glass particles onto the solar wafer with the passivation layer(s) and then heating the wafer up to temperatures at about 900° C. At such high temperatures the paste will etch its way through the passivation layer(s) and upon contact with the underlying silicon substrate, form a metallic phase establishing electric contact with the silicon substrate. However, such high temperatures are not acceptable for many of the presently assumed best passivation techniques.

### OBJECTIVE OF THE INVENTION

The main object of this invention is to provide methods for contacting silicon wafers that are surface passivated with deposited layers sensitive to thermal treatments.

A further objective is to provide novel silicon based solar cells with excellent surface passivation based on depositing a first layer of amorphous silicon and a second layer of silicon nitride.

### LIST OF FIGURES

FIG. 1a), 1b), and 1c) shows a cross sectional view of a wafer at different stages during production of a solar wafer according to a first preferred embodiment of the invention. FIG. 1a) shows the wafer after deposition of the passivation layers, 1b) after preparing the openings in the passivation layer, and 1c) after formation of the contacts.

FIG. 2a) shows a facsimile of FIG. 1 of [1], and FIG. 2b) shows a facsimile of FIG. 2 of [1].

FIG. 3a), 3b), and 3c) shows a cross sectional view of a wafer at the similar production stages as shown in FIG. 1 during production of a solar wafer according to a second preferred embodiment of the invention.

FIG. 4 shows a cross sectional view of the second surface of a partially processed wafer, after deposition of the aluminium layer on the second surface, during production of a fourth preferred embodiment of the invention.

FIG. 5 shows a cross sectional view of a first preferred method for locally heating the aluminium layer in order to establish electric contacts on the backside of the fourth preferred embodiment of the invention.

FIG. 6 shows a cross sectional view of a second preferred method for locally heating the aluminium layer in order to establish electric contacts on the backside of the fourth preferred embodiment of the invention.

### DESCRIPTION OF THE INVENTION

The objectives of the invention may be obtained by the features set forth in the following description of the invention and/or in the appended claims.

In a first aspect, the invention is based on the realisation that the contacting of a solar wafer containing one or more layers of thin dielectric, insulating or semi-conducting layers functioning as passivation layers may be obtained by first creating local openings in the passivation layer(s) and then fill the openings with a metal phase by use of for instance the electroplating technique to obtain electric contact with the underlying silicon substrate. In this way, it becomes possible to avoid the relatively high temperatures needed in the conventional method for contacting solar wafers containing one or more passivation layer(s), and thus maintain the excellent passivation properties of the passivation layer(s) during and after the contacting.

The opening of the one or more passivation layer(s) may be obtained by for instance etching techniques where a chemical agent dissolves the passivation layer(s) at specified local areas on at least one surface of the solar wafer, this may be obtained by ink-jet printing of an etching agent, screen-printing of an etching agent, by screen-printing a chemical resist followed by immersion of the solar wafer in an etching fluid, etc. The chemical etching agent may consist of, but are not limited to, diluted or concentrated HF, KOH, NaOH, or a mixture comprising HF, HNO₃, and CH₃COOH. An alternative method of obtaining the openings in the passivation layer(s) may be localised heating burning the passivation layer away, for instance by exposure to a laser beam.

The one or more passivation layer(s) should at least be applied to the first surface (the face receiving the sun light), but may also be applied on the opposite side (backside) of the solar wafer. The term passivation layer means at least one layer of a thin dielectric, insulating or semi-conducting compound that prolongs the recombination lifetimes at the surface of the silicon wafer. The passivation layer(s) may be on or more layer of the same chemical composition or it may be two or more layers of different chemical compositions. The passivation layer(s) on the second surface of the solar wafer may or may not have a similar structure as the one or more layers on the first surface. Further, the choice of passivation layer(s) is not important as long as it is possible to locally open the layer(s) at temperatures not destroying the passivation effect of the layers by for instance local heating with laser beam, chemical etching etc. Thus all presently known and not yet discovered dielectric, insulating or semi-conducting layers functioning as passivation layers may be employed that satisfies this condition. Examples of preferred passivation layers are amorphous silicon, amorphous silicon nitride, silicon oxide, or combinations of these. Examples of preferred methods for deposition of the one or more passivation layer(s) include, but are not limited to; plasma enhanced chemical vapour deposition, low temperature chemical vapour deposition, low pressure chemical vapour deposition, or sputtering.

As mentioned, after creating openings in the one or more surface passivation layer(s), the openings must be filled with an electrically conducting material in order to obtain electric contact with the silicon substrate below the one or more passivation layer(s). This may be obtained by for instance electroless plating or electroplating of nickel, silver, copper, and/or tin, or any combination of these materials. The invention is not restricted to these choices of metals, it may apply any material that provides a good electric contact with the underlying silicon substrate and which is resistant towards UV-light, temperatures up to about 150-250° C. and any other disruptive force/physical condition associated with normal use of solar panels during the expected lifetime of a solar panel and of subsequent manufacturing steps after formation of the contacts. This may include known electric conducting plastics and/or other polymer formulations such as carbon polymers, etc. There may be used the same materials as contacts on both sides of the wafer, or there may be employed different contact materials on each side. It is not given any restriction on the required electric conductance of the material employed for forming the contacts, since this requirement is strongly dependent upon the geometry and dimensions of the solar cells/panels that is to be contacted and a skilled person will know which conductivity which is required.

Optionally, the electrical contacts may be reinforced by forming metal contacts, by for instance ink-jet printing or screen-printing of a metal containing paste atop the plated contacts, followed by heating at temperatures that are sufficiently low as to not non-reversibly degrade the passivation layer(s). Further, another optional reinforcement of the contact sites of the solar wafer is forming contact points by for instance ink-jet printing or screen-printing of a metal containing paste directly on the wafer before the one or more passivation layer(s) is/are applied. In a preferred embodiment of the invention, the paste printed on the first surface contains silver particles, and the paste printed on the second surface contains aluminium particles. Subsequent to the printing of pastes, the paste is sintered by annealing at temperatures up to 1000° C. When these contact points have been made, the entire solar wafer including contact points is then subject to deposition of one or more passivation layer(s) as described above. Then the passivation layer(s) covering the contact points are removed as described above, and the openings are filled by ink-jet printing or screen-printing of metal based pastes in the openings, followed by a subsequent anneal at temperatures not exceeding detrimental temperatures for the one or more passivation layer(s). Alternatively, aluminium based metal contacts may be made by either sputtering or evaporation of an aluminium layer covering the whole second surface including the openings, or by screen-printing of an aluminium based metal paste covering the whole second surface including the openings. The sample is then optionally annealed at temperatures not exceeding detrimental temperatures for the one or more passivation layer(s).

The passivation effect is reported to be non-reversibly degraded at 300-350° C. in the case of using silicon nitride films, at less than 400° C. for amorphous silicon films, and at >500° C. for combined amorphous silicon and silicon nitride films.

In a second aspect of the invention, the contacting of the second surface of the solar wafer (the backside) may be obtained by depositing a thin aluminium containing layer of thickness in the range of approximately 30-50)μm on top of the one or more passivation layers, and then obtain the contacting by locally heating the aluminium layer at specific areas until the aluminium layer “burns” through the one or more passivation layer(s) and establishes electric contact with the underlying silicon substrate. Methods for deposition of the aluminium containing layer includes, but are not limited to, sputtering or evaporation of an aluminium layer at temperatures from about room temperature to about 200° C. covering the whole second surface, or by screen printing of an aluminium based metal paste covering the whole second surface. In the case of screen printing an aluminium containing paste, it is understood the use of commercial thick film pastes containing aluminium particles and that may or may not contain glass particles, followed by a bake-out of any organic solvents at temperatures <400° C. The localised heating of areas that are to be formed into contact points may be obtained by a heat member with needles or “bumps” in physical contact with the second surface of the partially processed solar cell. The partially processed solar cell should preferably be cooled by a cooling member in contact with the first surface, as well as in the areas of the second surface where contacts are not to be made during heating of the contact points. Alternatively, the second surface of the partially processed solar cell may be heated by infra-red radiation from a close proximity heat source, through openings in a cooling member. The cooling member is in physical contact with the second surface of the partially processed solar cell, ensuring that local heating occurs mainly within the openings of the cooling member. The partially processed solar cell should preferably also be cooled by a cooling member in physical contact with the first surface. Another alternative method for locally heating the second surface of the partially processed solar cell may be by use of a laser beam.

The invention concerns methods for thermally gentle contacting of wafers, and wafers formed by these methods. Thus the invention will function for any known semiconductor wafer, including mono-crystalline, multi-crystalline wafers of Si, Ge and other semi-conducting metals. Further, there is no restrictions regarding choice of doping element for forming the p-n or n-p junctions or physical dimensions of the doped layers, the semiconductor substrate etc. The wafer may be doped at one side or have doped layers at both sides. The choice of materials, dimensioning and production of wafers is known to skilled persons, and need no further description.

### PREFERRED EMBODIMENTS OF THE INVENTION

The invention will be described in more detail in the form of preferred embodiments, which by no means should be considered a limitation of the inventive idea of obtaining the contacting by first preparing openings in the passivation layer(s) and then fill these openings with electrically conducting materials that form an electric contact with the underlying silicon substrate by process steps that do not involve temperatures detrimental to the passivation effect of the remaining passivation layer(s). The preferred embodiments of the solar panels are based on silicon wafers which may be made from a mono-crystalline silicon or multi-crystalline silicon block. Solar grade silicon is chosen as the preferred material due to cost considerations, but it is emphasised that the invention will function with use of other semi-conducting metals. All manufacturing steps for obtaining a wafer made ready to surface passivation are not relevant for this invention, and are therefore not described in this patent application.

### First Preferred Embodiment of the Invention

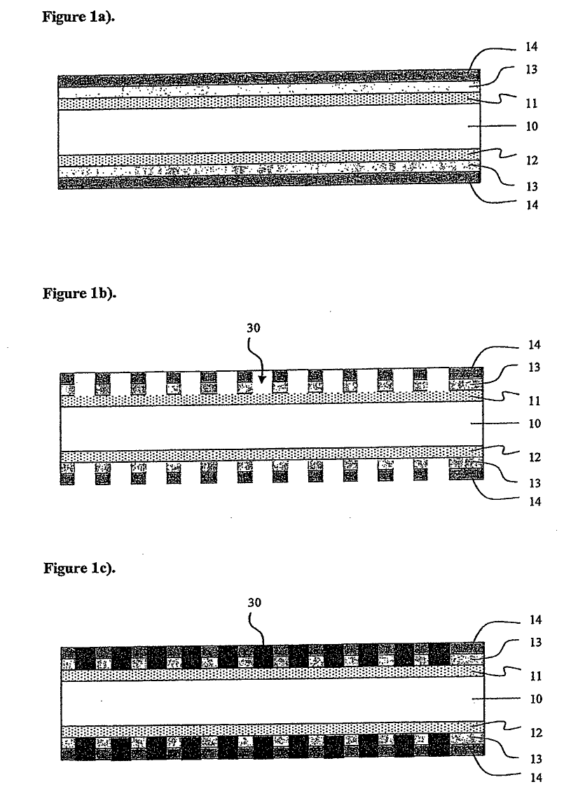

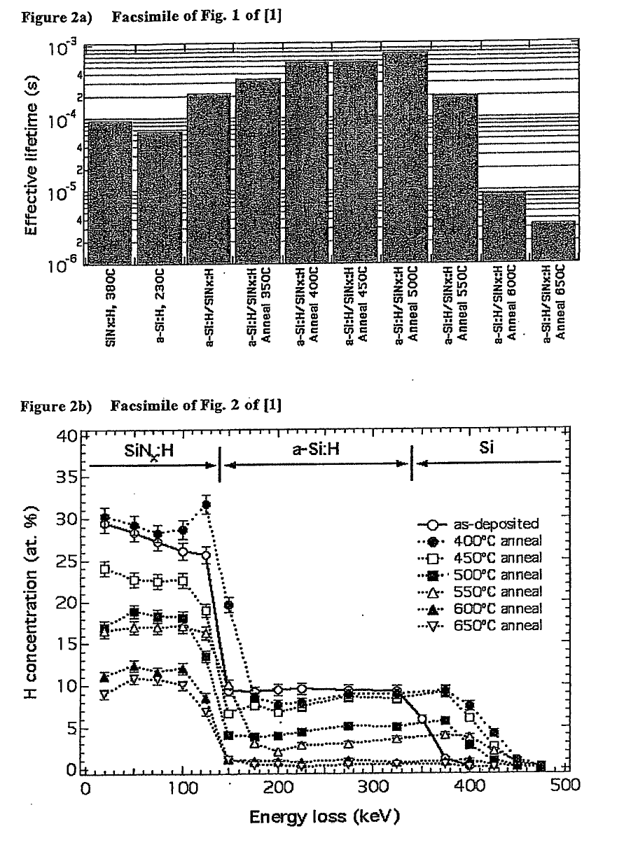

The first preferred embodiment of the invention is a preferred production method of a preferred solar cell according to the invention. This is presented schematically by cross sectional views of a semiconductor wafer at different process steps in FIG. 1, part a), b), and c) respectively.

Part a) of FIG. 1 shows a cross sectional view of a silicon semiconductor wafer just after deposition of the surface passivation layers. The wafer comprises one layer (10) of one type conductivity (p- or n-type) containing a thin diffused layer (11) of the other type of conductivity at the first surface of the wafer (10), to form the p-n or n-p junction. The figure also illustrates an alternative wafer (10) of one type conductivity (p- or n-type) with a thin diffused layer (11) of the other type of conductivity at the first surface of the wafer (10), and a thin diffused layer (12) of the one type conductivity at the other surface of the wafer (10). It is optional to use either one doped layer (11), or one doped layer (11) and one doped layer (12) in the first preferred embodiment.

The surface passivation in the first preferred embodiment is obtained as follows: The wafers (10, 11, 12) are cleaned by immersion in mixture of H₂SO₄ and H₂O₂, a mixture of HCl, H₂O₂ and H₂O, or a mixture of NH₄OH, H₂O₂ and H₂O, followed by an oxide removal in diluted HF. Then the wafers are introduced into a plasma enhanced chemical vapour deposition chamber (PECVD-chamber), and an amorphous silicon film with thickness 1-150 nm, preferably around 10-100 nm is deposited by use of SiH₄ as sole precursor gas. The amorphous silicon film is deposited on both surfaces of the wafers and is denoted by reference number (13) in the figures. Then a layer of silicon nitride is deposited by use of a mixture of SiH₄ and NH₃ as precursor gases in the PECVD-chamber. The thickness of the silicon nitride film should be in the range of 10-200 nm, preferably around 70-100 nm. The precursor gases may also comprise from 0 to 50 mol % hydrogen gas. The silicon nitride film is deposited on both sides of the wafers and is denoted by reference number (14) in the figures. The deposition temperature in the PECVD-chamber is about 250° C. for both films. The passivation procedures is finalised by heating the wafers to a temperature in the range of 350-550° C., preferably around 500° C. for four minutes. This annealing may be performed at subsequent process stage after deposition of the passivation layers, for example after metallization.

The studies by the present inventor shows that the best mode of the passivation layers is a dual 10-100 nm amorphous silicon and 70-100 nm silicon nitride that is annealed at 500° C. FIG. 1 in [1] shows that a dual 80 nm amorphous silicon and 100 nm silicon nitride film gives an effective recombination lifetime of 0.0007 s, which is about 1 order of magnitude better than single films of amorphous silicon or silicon nitride, or 2-3 times higher than a dual film of amorphous silicon and silicon nitride that is not annealed. Without being bound by theory, the reason for the markedly increased passivation effect is believed to be due to diffusion of hydrogen atoms into the boundary region of the crystalline silicon substrate which satisfies dangling bonds in the crystalline silicon. FIG. 2 of [1] shows measured distributions of hydrogen in the dual passivation layer and adjacent to the interface region of the bulk silicon wafer after different annealing temperatures. The figure shows that the optimum annealing temperature of 500° C. results in a maximum in the hydrogen content adjacent to the interface region of about 10 atom % H. Annealing at higher or lower temperatures gives lesser hydrogen contents. A facsimile of FIG. 1 and FIG. 2 of [1] is given in this application as FIG. 2a) and b), respectively.

FIG. 1b) shows the wafer after openings (30) has been made in the passivation layers (13, 14), such that access to the underlying substrate (10, 11, 12) may be obtained. These openings are made by ink-jet printing a chemical etching agent comprising a solution diluted or concentrated HF, KOH, NaOH, or a mixture comprising HF, HNO₃, and CH₃COOH, or a combination thereof. The choice of method for obtaining the openings (30) is not important. The vital feature is that the passivation layers (13, 14) must be locally removed to expose the wafer (10, 11, 12) at the positions on the wafer where the contacts are to made. The remaining area of the wafer (10, 11, 12) surface must be covered with the passivation layers (13, 14).

The wafer (10, 11, 12) after formation of electric contacts (41, 42) in the openings (30) is shown in FIG. 1c). A preferred method for producing the electrical contacts that establishes electric contact with the wafer (10, 11, 12) is electroplating or electroless plating of nickel, silver, copper, and/or tin, or any combination of these materials. Optionally, the electrical contacts may be reinforced by forming metal contacts, by for instance ink-jet printing or screen-printing of a metal containing paste atop the plated contacts.

After formation of the electric contacts (41, 42), the wafer is ready for assembly into a solar panel by for instance introducing bus bars etc. The remaining process steps are well known to a person skilled in the art, and need no further description.

### Second Preferred Embodiment of the Invention

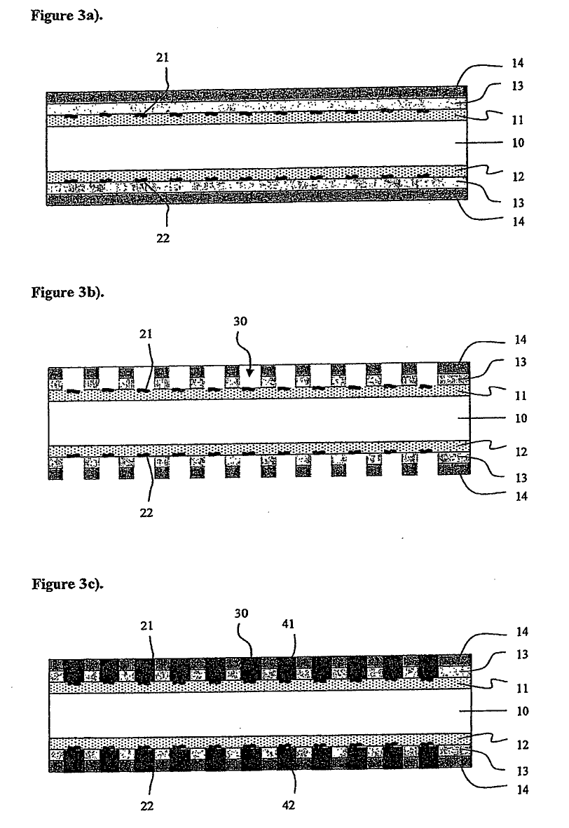

The second preferred embodiment of the invention is similar to the first preferred embodiment except that the contacting of the wafer is reinforced by creating contact points (21, 22) before passivation of the surfaces (10, 11, 12) of the wafer. The process of the second preferred embodiment is schematically presented in FIG. 3a) to 3c), in the same stages as the first preferred embodiment is shown in FIG. 1a) to 1c).

The contact points (21, 22) are made by ink-jet printing a thin paste containing silver particles at the sites on the surface of the thin diffused layer (11) where the contacts (21) are to be made. At the other side, a thin paste containing aluminium particles is printed ink-jet printed at the sites of the surface of the thin diffused layer (12) where the contacts (22) are to be made. Actual pastes suited for this purpose are known to the skilled person and available as commercial products, and need no further description.

Subsequent to the printing of pastes, the paste is sintered by annealing at temperatures up to 1000° C. Following the sintering of the contact regions (21) and (22), the partially processed solar cell is etched in a solution in order to remove excessive parts of the metallic layers remaining on the surfaces. The solution can contain, but is not limited to, a mixture of H₂O₂ and H₂SO₄, a mixture of H₂O₂, NH₄OH, and H₂0, or a mixture of H₂O₂, HCl, and H₂O.

After formation of the contact points (21, 22) and removal of excess metal remains on the surfaces of layers (11, 12), the wafers are processed in the same manner as described for the first preferred embodiment.

### Third Preferred Embodiment of the Invention

The third preferred embodiment of the invention is an alternative contacting of the second surface (back surface) that may be applied on both the first and second preferred embodiment of the invention.

The alternative contacting of the second surface of the wafer is obtained by either sputtering or evaporation of an aluminium layer covering the whole second surface including the openings (30), or by screen-printing of an aluminium based metal paste covering the whole second surface including the openings (30). In the latter case, the sample is then optionally annealed at temperatures up to, but not exceeding 500° C.

In all other aspects, the third preferred embodiment is similar to the first or second preferred embodiment.

### Fourth Preferred Embodiment of the Invention

The forth preferred embodiment is an alternative method of obtaining the alternative contacting of the second surface presented in the third embodiment.

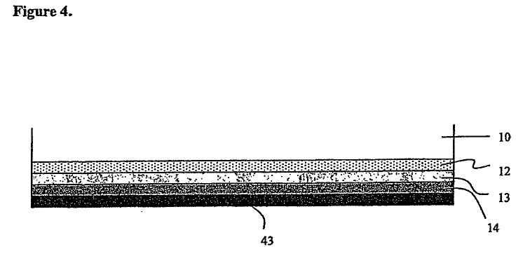

In this alternative, there is not made any openings in the passivation layers (13, 14) on the second surface, but instead the passivation layer (14) is covered by an aluminium layer (43), see FIG. 4. The processing of the first surface of the wafer is similar as the process described for the first or second preferred embodiment. As for the third preferred embodiment, the method for depositing the aluminium containing layer (43) includes, but are not limited to, sputtering or evaporation of an aluminium layer covering the whole second surface, or by screen printing of an aluminium based metal paste covering the whole second surface followed by a gentle annealing as described above.

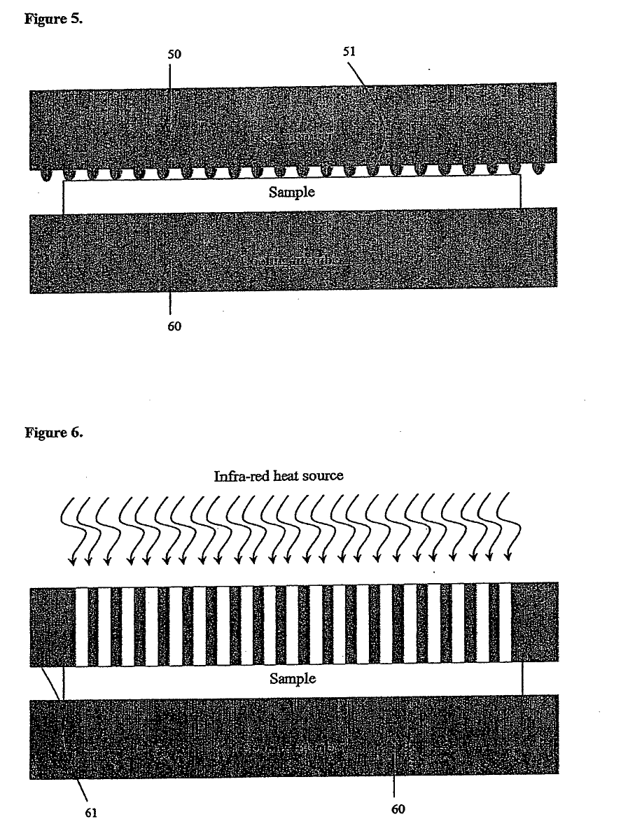

After formation of the aluminium layer (43), the wafer is laid with the first side facing down on an underlying cooling member (60), see FIG. 5. Then a heating member (50) with a series of hot needle-like protrusions (51) are pressed onto the second surface of the wafer in order to locally heating the aluminium layer (43) until it “burns” it way through the passivation layers (13, 14) and establishes electric contact with the underlying wafer (12). Without being bound by theory, it is assumed that the local temperature of the aluminium layer should reach about 650° C. in order to obtain penetration through the passivation layers and thus establish contact with the wafer. This process is illustrated in FIG. 5. The cooling member (60) is optional, but is preferred since it ensures that the passivation layers of the partially processed solar cell is cooled at the first surface as well as in the areas of the second surface where contacts are not to be made.

FIG. 6 shows an alternative method for locally heating the aluminium layer (43), using an infra-red radiation from a close proximity heat source, through openings in a cooling member (61). The cooling member (61) is in physical contact with the second surface of the partially processed solar cell, ensuring that local heating occurs mainly within the openings of the cooling member (61). It is preferred to employ a cooling member (60) in physical contact with the first surface, for the same reasons as given above.

### REFERENCES

1. Andreas Bentzen et al. “Surface Passivation of Silicon Solar Cells by Amorphous Silicon/Silicon Nitride Dual Layers”, presented at 15^{th} International Photovoltaic Science & Engineering Conference (PVSEC-15), Shanghai, China, 19^{th} May 2005

1-19. (canceled)

20. A method for contacting a metallic semiconductor wafer,
where the wafer has
at least one thin diffused layer of one type of conductivity (p- or n-type) on one side of the wafer, and the bulk wafer has the other type of conductivity (n- or p-type), and
at least one deposited surface passivation layer/film on at least one of the first (light receiving side) or second (back side) surface,
wherein
forming a contact site by creating at least one opening in the at least one passivation layer by locally removing the at least one passivation layer to expose the underlying surface of the semiconductor wafer, and then
establishing electric contact with the semiconductor wafer by filling the at least one opening in the at least one passivation layer with an electrically conducting material that is UV-light resistant and functional at temperatures up to at least about 150 to 250° C. by employing one of the following techniques: electroless plating or electroplating, or ink-jet printing or screen-printing of a paste containing the electricity conducting material followed by a gentle annealing up to 550° C. or less, depending on the heat sensitivity of the passivation layer(s).

21. A method according to claim 20,
where the at least one contact site(s) is/are reinforced by forming a contact point on each of the at least one contact site(s) before formation of the at least one passivation layer(s), wherein the at least one contact point(s) is/are made by:
ink-jet printing a thin paste comprising silver particles on each of the at least one contact sites on the first surface of the semiconductor wafer,
ink-jet printing a thin paste comprising aluminium particles on each of the at least one contact sites on the second surface of the semiconductor wafer,
annealing the deposited paste(s) on the first and second surface of the wafer at temperatures up to 1000° C. to form metallic contact points, and finally
etching away excess metal deposits on the contact points by immersion in an etching solution which is one or more of the following; a mixture of H₂O₂ and H₂SO₄, a mixture of H₂O₂, NH₄OH, and H₂0, or a mixture of H₂O₂, HCl, and H₂O.

22. A method according to claim 21,
wherein the thin paste comprising silver particles and/or the thin paste comprising aluminium particles is/are screen-printed onto the first and/or second surface of the wafer, respectively.

23. A method according to claim 20,
wherein the surface passivation of at least one of the first or second surface of the semiconductor wafer is obtained by
cleaning the semiconductor wafer by immersion in a mixture of H₂SO₄ and H₂O₂, or a mixture of HCl, H₂O₂ and H₂O, or a mixture of NH₄OH, H₂O₂ and H₂O,
removing the oxide film on the wafer side(s) that is/are to be passivated by immersion in diluted HF,
introducing the wafer into a plasma enhanced chemical vapour deposition chamber (PECVD-chamber),
depositing a 1-150 nm thick amorphous silicon film by use of SiH₄ as sole precursor gas at about 250° C.,
depositing a 10-200 nm thick silicon nitride film by use of a mixture of SiH₄ and NH₃ as precursor gases at about 250° C., and finally
annealing the wafer with the deposited passivation at a temperature in the range from about 350 to about 550° C.

24. A method according to claim 23,
wherein
the precursor gases also comprises from 0 to 50 mol % hydrogen gas.

25. A method according to claim 23,
wherein
the amorphous silicon film is about 10-100 nm thick,
the silicon nitride film is about 70-100 nm thick, and
the annealing is performed at a temperature of about 500° C. for four minutes.

26. A method according to claim 25,
wherein the localised opening of the one or more passivation layer(s) is obtained:
by use of an etching agent that is either ink-jet printed or screen-printed onto the region(s) of the at least one passivation layer covering the contact site(s), or
by screen-printing a chemical resist covering the areas of the at least one passivation layer(s) that are to remain on the wafer, followed by immersion of the solar wafer in an etching agent to remove the unprotected passivation film(s).

27. A method according to claim 26,
wherein
the chemical etching agent comprises one or more of the following agents; a solution comprising diluted or concentrated HF, or KOH, or NaOH, or a mixture comprising HF, HNO₃, and CH₃COOH.

28. A method according to claim 23,
wherein the localised opening of the one or more passivation layer(s) is obtained by local heating of the area of the passivation layer(s) covering the contact sites by exposure to a laser beam.

29. A method according to claim 20,
wherein the at least one electric contact(s) with the semiconductor wafer is obtained by filling the at least one opening in the at least one passivation layer(s) by an electricity conducting material comprising one or more of the following materials; nickel, silver, copper, and/or tin, or any combination of these materials.

30. A method according to claim 20,
wherein the contacting of the second surface (backside) of the wafer is obtained by
depositing a layer of aluminium on top of the at least one passivation layer(s), and
pressing a heating member with a series of hot needle-like protrusions onto the deposited aluminium layer in order to locally heating the aluminium layer until it “burns” it way through the passivation layers and establishes electric contact between the aluminium layer and underlying wafer.

31. A method according to claim 30,
wherein
the local temperature of the aluminium layer in contact with the heating element is about 650° C., and that
a cooling element is placed in contact with the first surface (light receiving surface) of the wafer during heating.

32. A method according to claim 20,
wherein the contacting of the second surface (backside) of the wafer is obtained by
depositing a layer of aluminium on top of the at least one passivation layer(s), and
locally heating the contact sites on the deposited aluminium layer in order to allow the aluminium phase to “burns” through the passivation layers and establishes electric contact between the aluminium layer and underlying wafer by use of electromagnetic radiation.

33. A method according to claim 32,
wherein
the local temperature of the aluminium layer in contact with the heating element is about 650° C.,
a cooling element is placed in contact with the first surface (light receiving surface) of the wafer during heating, and that
the electromagnetic radiation is an infra-red radiation or a laser beam.

34. A method according to claim 20,
wherein the semiconductor wafer is one of monocrystalline or multicrystalline silicon.

35. A solar cell comprising
a silicon semiconductor wafer of one type of conductivity (p- or n-type) having a at least one thin diffused layer of the other type conductivity (n- or p-type), and
at least one deposited surface passivation layer/film on at least one of the first (light receiving side) or second (back side) surface,
at least one contact site point at the first and second surface establishing electric contact with the wafer, and
at least one electric contact on both sides of the wafer,
wherein
the at least one passivation layer(s) is formed by using at least one hydrogen containing precursor gas in a plasma enhanced chemical vapour deposition chamber (PECVD-chamber) followed by a gentle annealing such that at least a portion of the free bonds in the surface region of the silicon semiconductor wafer is satisfied by in-diffusion of hydrogen atoms.

36. A solar cell according to claim 35,
wherein the surface passivation of at least one of the first or second surface of the semiconductor wafer comprises
a 1-150 nm thick amorphous silicon film and a 10-200 nm thick silicon nitride film, and which is
subsequently annealed at a temperature in the range from about 350 to about 550° C. in order to introduce hydrogen atoms into the surface region of the wafer underlying the deposited films.

37. A solar cell according to claim 36,
wherein
the amorphous silicon film has a thickness about 10-100 nm,
the silicon nitride film has a thickness about 70-100 nm, and in that
the subsequent annealing was performed at about 500° C. for four minutes in order to introduce about 10 atom %, H in the surface region of the semiconductor wafer underlying the deposited films.

38. A solar cell according to claim 35,
wherein the semiconductor wafer is one of monocrystalline or multicrystalline solar grade silicon.
